(19) United States
(12) Patent Application Publication
(10) Pub. No.: US 2011/0192450 A1
(43) Pub. Date: Aug. 11, 2011

(54) METHOD FOR PRODUCING NANOPARTICLE SOLUTIONS BASED ON PULSED LASER ABLATION FOR FABRICATION OF THIN FILM SOLAR CELLS

(76) Inventors: Bing LIU, Ann Arbor, MI (US); Yong Che, Ann Arbor, MI (US)

(21) Appl. No.: 12/951,585

(22) Filed: Nov. 22, 2010

Related U.S. Application Data
(60) Provisional application No. 61/302,995, filed on Feb. 10, 2010.

(51) Int. Cl. H01L 31/0256; B01J 19/12; B82Y 40/00

(52) U.S. Cl. 136/252; 204/157.41; 977/901

(57) ABSTRACT

A method of producing nanoparticles of solar light absorbing compound materials based on pulsed laser ablation is disclosed. The method uses irradiation of a target material of solar light absorbing compound material with a pulsed laser beam having a pulse duration of from 10 femtoseconds to 500 picoseconds to ablate the target thereby producing nanoparticles of the target. The nanoparticles are collected and a solution of the nanoparticles is applied to a substrate to produce a thin film solar cell. The method preserves the composition and structural crystalline phase of the starting target. The method is a much lower cost fabrication method for thin film solar cells.

### RELATED APPLICATIONS

This application claims the benefit of U.S. provisional application Ser. No. 61/302,995 filed Feb. 10, 2010.

### STATEMENT REGARDING FEDERALLY SPONSORED RESEARCH

NONE

### FIELD OF THE INVENTION

This invention is related to producing thin film solar cells and, more particularly, to using pulsed laser ablation of a source material in a liquid for producing nanoparticle solutions for use in the fabrication of thin film solar cells.

### BACKGROUND OF THE INVENTION

Compared with single crystal solar cells, thin film solar cells consume far less source material and therefore are less costly to produce. In current thin film solar cell fabrication, the light absorbing layer, which is the most critical layer, is fabricated mostly using vacuum methods, such as thermal evaporation, chemical vapor deposition and sputtering. For compound solar absorbing materials compounds composed of group II-VI elements, like CdTe, or group III-V elements, or group IB-III-VI₂ elements such as the chalcopyrites CuInSe₂ and CuIn₁₋ₓGaₓSe₂, precise control of the film composition is necessary. Controlling the atomic ratio between the constituent elements is the key to ensuring the correct structural phase and the desired electrical conductivity, hole conduction and good hole mobility, of the film. For example, for CIGS films comprising CuIn₁₋ₓGaₓSe₂ with x˜0.2-0.3, the atomic ratio between the constitute elements Cu:(In+Ga):Se should be near 25%:25%:50%, with allowable fluctuation of less than a few percent. Deviation from this compositional ratio causes problems with electrical conductivity, behavior of native defects, band gap, and structural phase, eventually lowering the conversion efficiency of the solar cell.

Achieving the required end points using thermal evaporation, requires careful monitoring and control of the evaporation rate of each individual elemental source and uniform overlap of the vapor beams. Such fabrication processes involve complex parameter control in the production line, which is a major factor of the high production cost of this method. In addition, there are issues with the difficulty of depositing uniform films and precursor phase segregation.

To avoid the above problems, non-vacuum and solution-based printing methods have been developed. In these methods, the elemental source materials are first made into small sub-micron particles and dispersed into solvents. After mixing with appropriate binders, the solution becomes a dense paste and is suitable for printing thin films. U.S. Pat. No. 6,268,014 discloses a method based on mechanical milling to produce sub-micron-scaled metal oxide and selenide fine powders. The precursor powders of the constitute elements, meaning CuₓO, In₂O₃, and CuₓSe are then mixed in a calculated weight ratio and dispersed into solutions to make pastes for spray printing. One difficulty with this method is related to the average particle size and size distribution, which determine the packing density. Mechanical milling can produce sub-micron particles down to a few hundred nanometers, which still leaves unfilled pores of tens of nanometers in the product films. Thus, to ensure pinhole-free layers you need to use more material raising costs of production.

U.S. Pat. No. 7,306,823 discloses a method of making solutions of nanometer-sized particles called nano-inks for printing compound CIGS films. In this method, one of the elemental source materials, such as Cu, is first made into nanoparticles with diameters between a few tens to a few hundreds of nanometers and dispersed into a solution. The Cu particles are then coated with layers of In and Ga using electrochemical methods. This process is time consuming and very costly. In addition, the required In and Ga layer thickness for the correct stoichiometry depend on the Cu core sizes, which becomes difficult to control when the size distribution is large.

For nanoparticles of simple binary compound materials such as CdSe, there have been many successful solution-based synthesis methods. However, for complex materials such as CIGS, precise control of the composition is still challenging. For example, when using metal oxides as precursors, high temperature hydrogen reduction is needed to reduce the metal oxides, which is very costly both in time and in energy. This is because most metal oxides are thermodynamically very stable e.g., the formation enthalpies of In₂O₃ and Ga₂O₃ are both below −900 kJ/mol, while the formation enthalpy of water is −286 kJ/mol. Incomplete reduction will result in not only impurity phases but also an incorrect composition.

Recently, pulsed laser ablation has been shown to produce elemental metal nanoparticles in various liquids. The process is based on laser-induced evaporation of the target materials. Typical pulsed lasers include Excimer and Nd:YAG lasers, which can provide laser pulses with a pulse duration of several nanoseconds (ns) and a pulse energy of several hundred milli-Joules (mJ). Because of the extreme high peak power, ˜GW, of these short laser pulses when they are focused on the target surface the fluence, defined as the area power density in W/cm² or more conveniently as the area energy density in J/cm² when the pulse duration is known, readily exceeds the ablation threshold of most materials, and the material under irradiation is instantaneously evaporated. When the ablation is performed in a liquid such as water, the laser induced vapor quickly re-nucleates under the liquid confinement and nanometer-sized particles are formed. This method has been used to successfully produce noble metal nanoparticles in water and other liquids.

For compound materials, the inventors of the current method recently demonstrated that with pulsed lasers, meaning those with a pulse duration of 500 picoseconds or less, the composition of the target material can be preserved during ablation such that the product nanoparticles have the same stoichiometric composition as the target. In addition, the product nanoparticles also maintain the same crystal structure as the target material. It is believed that these results are possible as a direct consequence of the pulsed laser ablation being conducted under the appropriate fluence range. It is theorized that when the time scale of target material disintegration is shorter than the time scale of composition variation and structural change, the initial composition and crystal structure are preserved during the transition from the bulk target to the nanoparticle products.

It is highly desirable to develop a process for producing thin film solar cells that is rapid, highly reproducible and less expensive than existing methods. It is also desirable to produce a method that can be adapted to a wide variety of starting materials and that it not limited by the starting materials.

### SUMMARY OF THE INVENTION

The present invention is a one-step method based on pulsed laser ablation of target materials to produce nanoparticles of solar light absorbing compound materials in a liquid. The nanoparticles can then be used for fabrication of thin film solar cells. Using the method the product nanoparticles maintain the compound composition and the crystalline structure of the starting material. The invention is a method of producing nanoparticles of solar light absorbing compound materials, comprising the steps of: providing a target of a solar light absorbing compound material; irradiating the target with a pulsed laser beam having a pulse duration of from 10 femtoseconds to 100 nanoseconds, more preferably from 10 femtoseconds to 200 picoseconds and ablating the target thereby producing nanoparticles of the target; and collecting the nanoparticles, wherein the nanoparticles maintain the stoichiometry and crystalline structure of the target.

In various embodiments the target materials are made of solar light absorbing compound material semiconductors. By way of example, production of CIGS nanoparticles using the present invention is shown. As a quaternary compound, CIGS is the most complex material currently used for solar light absorbers in thin film solar cells. The current invention produces CIGS nanoparticles with the correct chemical composition. In addition, the current invention produces CIGS thin films with the correct chalcopyrite crystal structure of CIGS. Adding appropriate binder materials to the solutions can make more dense pastes and speed up the process, and subsequent annealing can improve the quality of the films.

### BRIEF DESCRIPTION OF THE DRAWINGS

FIG. 1 is a schematic illustration of a laser ablation system in accordance with the present invention;

FIG. 2 schematically illustrates the steps of forming a thin film from a nanoparticle solution in accordance with the present invention;

FIG. 3 shows an electron photomicrograph of a cross-section of a CIGS film produced in accordance with the current invention;

FIG. 4 shows an Energy Dispersive X-ray (EDX) spectrum of a CIGS film produced in accordance with the present invention; and

FIG. 5 shows an X-ray Diffraction pattern of the structural phase of a CIGS film produced in accordance with the present invention.

### DETAILED DESCRIPTION OF THE INVENTION

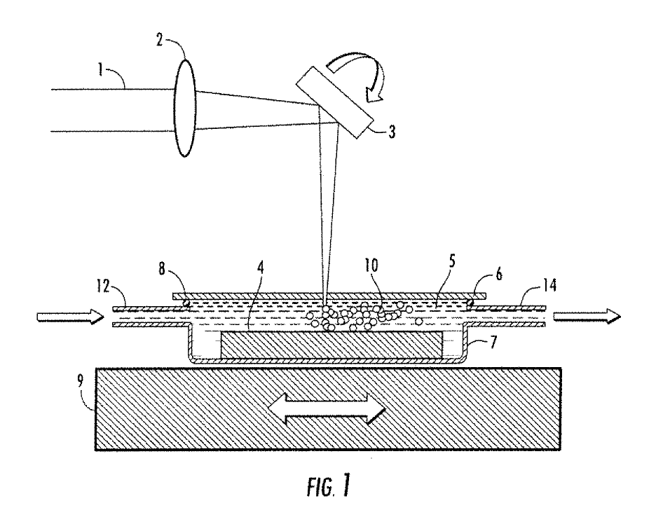

FIG. 1 schematically illustrates a laser-based system for producing nanoparticles of complex compounds in a liquid in accordance with the present invention. In one embodiment a laser beam 1 is received from a pulsed laser source, not shown, and focused by a lens 2. The source of the laser beam 1 can be a seed laser or any other laser source as known in the art provided it has the pulse duration, repetition rate and power level as discussed below. The focused laser beam 1 then passes from the lens 2 to a guide mechanism 3 for controlling movement of the laser beam 1. The guide mechanism 3 can be any of those known in the art including by way of example piezo-mirrors, acousto-optic deflectors, rotating polygons, vibration minor, and prisms. Preferably the guide mechanism 3 is a vibration mirror 3 to enable controlled and rapid movement of the laser beam 1. The guide mechanism 3 directs the laser beam 1 to a target 4. The target 4 is made from the desired solar light absorbing compound material as described below. For example, in one embodiment it is a disc of CIGS having the desired stoichiometric composition. It can also be any other suitable solar light absorbing compound material. The target 4 is submerged a distance of from several millimeters to preferably less than 1 centimeter below the surface of a liquid 5. Complete submersion of the target 4 in the liquid 5 is not required, as long as a portion of the target 4 is in contact with the liquid 5 the laser beam 1 can ablate at the target-liquid interface. A container 7 having a removable glass window 6 on top of the container 7 provides a location for the target 4. An O-ring type of seal 8 is placed between the glass window 6 and the top of the container 7 to prevent the liquid 5 from leaking out of the container 7. The container 7 includes an inlet 12 and an outlet 14 so the liquid 5 can be passed over the target 4 and so that it can be re-circulated. The container 7 is optionally placed on a motion stage 9 that can produce translational motion of the container 7 and movement of the liquid 5. Flow of the liquid 5 is used to carry generated nanoparticles 10 of the target 4 out of the container 7 to be collected elsewhere. The flow of liquid 5 over the target 4 also cools the laser focal volume. The flow rate and volume of liquid 5 should be sufficient to fill the gap between the target 4 and the glass window 6. In addition, it must be sufficient to prevent any gas bubbles generated during the laser ablation from staying on the glass window 6. The liquid 5 can be any liquid that is largely transparent to the wavelength of the laser beam 1 and that preferably is a poor solvent for the target material 4. In one embodiment, the liquid 5 is deionized water having a resistivity of greater than 0.05 MOhm·cm, and preferably greater than 1 MOhm·cm. In other embodiments it can be a volatile liquid such as ethanol or another alcohol or it can be liquid nitrogen or mixtures thereof. Using a volatile liquid as the liquid 5 can be of benefit when the collected nanoparticles 10 are collected and concentrated or when they are applied to a substrate to form the thin film solar cells. Other functional chemical agents can also be added to the liquid 5 during ablation. For example, surfactants such as sodium dodecyl sulfate (SDS) can be added to prevent particle coagulation in the liquid 5. Typical SDS molar concentrations can be between 10⁻³-10⁻¹ Molar/L (M). Surfactants are especially helpful for making dispersed particle solutions without coagulation when the laser pulse duration is in the range of 200 picoseconds to 100 nanoseconds.

In at least one embodiment the laser wavelength is 1000 nanometers which passes through water with minimal absorbance. The laser pulse repetition rate is preferably 100 kHz and above. The pulse energy is preferably 1 micro-Joule (μJ) and above. IMRA America Inc., the assignee of the present application, disclosed several fiber-based chirped pulse amplification systems which provide an ultrashort pulse duration from 10 femtoseconds to 200 picoseconds, single pulse energy ranging from 1 to 100 μJ, and a high average power of more than 10 watts (W). The pulse duration of the laser beam used according to the present invention is from 10 femtoseconds to 100 nanoseconds, more preferably from 10 femtoseconds to 200 picoseconds. Preferably the pulse energy is from 100 nanoJoules to 1 milliJoule and more preferably from 1 μJ to 10 μJ. The pulse repetition rate is from 1 Hz to 100 MHz, preferably less than 100 MHz, and more preferably from 100 kHz to 1 MHz. In various embodiments the laser used in ablation according to the present invention comprises in sequence: a seed laser with a high repetition rate of between 30 and 100 MHz which also typically includes an oscillator, a pulse stretcher, and a preamplifier; an optical gate to select pulses from the seed laser; and a final power amplifier that amplifies the selected pulses. These laser systems are especially suitable for the application in the current invention. The wavelength of these systems is typically 1030 nanometers. The present invention is not limited to that laser beam wavelength, rather second harmonic generation can be used to produce wavelengths in the visible and UV range. In general a wavelength in the regions of near infrared (NIR), visible, or UV can all be used in the present invention.

In one embodiment the guide mechanism 3 is a vibration mirror 3 that is configured for fast rastering or other movement of the laser beam 1 on the surface of the target 4. The vibration mirror 3 vibration frequency is preferably 10 Hz or greater and preferably it has an angular amplitude of 0.1 mrad or greater and more preferably of 1.0 mrad or greater, such that a rastering speed on the surface of the target 4 is 0.01 meters per second or greater and most preferably 0.1 meters per second or greater. Such a mirror 3 can be a piezo-driven mirror, a galvanometer mirror, or other suitable apparatus for movement of the laser beam 1.

The target 4 can be any suitable solar light absorbing compound material including binary, ternary and quaternary compound materials. Suitable binary compound materials can be selected from groups IIB and VIA of the periodic table, such as CdTe and CdSe. Suitable ternary compound materials can be selected from groups IB, IIIA and VIA of the periodic table, such as CuInSe₂ and CuInS₂. Suitable quaternary compound materials can be selected from groups IB, IIIA, and VIA, such as CuInGaSe₂ and CuInGaS₂. Other suitable quaternary compound materials can be selected from groups IB, IIB, IVA and VIA, such as Cu₂ZnSnS₄ and Cu₂ZnSnSe₄.

In one embodiment, flow of the liquid 5 through the container 7 is carried out by a circulation system, with a flow speed preferably of 1.0 milliliter per second or greater and more preferably of 10.0 milliliter per second or greater. Flow of liquid 5 is necessary to uniformly distribute the generated nanoparticles 10 in the liquid 5 and to remove them from the container 7. It is preferred to maintain a sufficient volume of the liquid 5 to avoid any fluctuations in the thickness of liquid 5 above the target 4. If the liquid 5 thickness varies it can change the optical path properties of the laser beam 1 and cause a broader distribution of sizes of the generated nanoparticles 10. The optical window 6 above the flowing liquid 5 helps to keep a constant thickness of liquid 5 above the target 4. When a circulation system is not available, introducing lateral vibration movement, for example perpendicular to the laser beam 1, as indicated in FIG. 1, to the motion stage 9 can also cause liquid 5 flow locally across the ablation spot. The motion stage 9 preferably has a vibration frequency of several Hz and an amplitude of several millimeters. A shaker can also be used to circulate the liquid 5, wherein the circular movement of the shaker causes the liquid 5 in the container 7 to have a circular movement too, therefore the nanoparticles 10 can distribute evenly in the liquid 5. With either of these two methods of circulating the liquid 5, the glass window 6 is not necessary; however, the use of either will introduce non-uniformity into the thickness of the liquid 5 above the target 4 and will cause a broader size distribution of the nanoparticles 10.

In one example the target is a thin disk of polycrystalline CIGS. The nominal atomic ratio between the constitute elements Cu:In:Ga:Se in the target is 25%: 20%:5%:50% according the target manufacturer, Konjudo Chemical Laboratory Co. Ltd. The quaternary compound material CIGS has a band gap of 1.0-1.2 eV. Using a laser beam with a wavelength of 1000 nanometers the corresponding photon energy is 1.2 eV, which is above the band gap of the CIGS material. The laser beam is therefore strongly absorbed by this target material. The optical absorption depth is estimated to be as small as ˜1μm. This results in a low ablation threshold, which is estimated to be around 0.1 J/cm². In practicing the current method a typical laser focal spot size is from 20 to 40 μm in diameter, more preferably about 30 μm in diameter. Using a focal spot size of 30 μm in diameter the minimum pulse energy required to ablate CIGS is about 0.7 μJ.

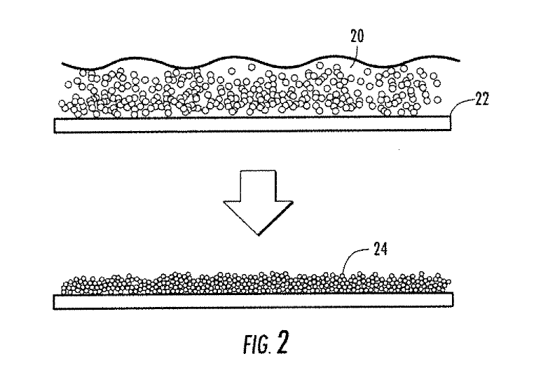

In the practice of the present invention the target material is placed in the container and the ablated nanoparticles are collected from the liquid as they are generated. The nanoparticles preferably have a size of from 2 to 200 nanometers. If required the nanoparticles can be concentrated by filtration or centrifugation as known in the art. This can also be done to change the liquid if necessary for the subsequent application of the nanoparticles to a substrate. FIG. 2 illustrates the two subsequent steps of making a thin film solar cell from the nanoparticles created by the present method. The nanoparticle suspension 20 is spread onto a substrate 22. After drying, the sediment of the nanoparticle suspension 20 forms a closely packed thin film 24. These two steps are common for most solution-based methods of forming solar cells and it is known in the art to add appropriate binders to make thicker pastes and to speed up the process. It is also known to anneal the formed film 24 in selenium vapor to enhance the structural quality of the film. Such steps can be practiced with the present invention. Various substrates 22 can be used, including semiconductors, glass, metal-coated glass, and metal plates and metal foils. Typical metal substrates include, but are not limit to, molybdenum, copper, titanium, and steel.

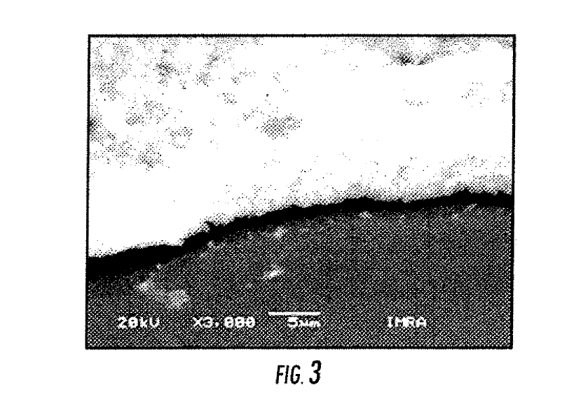

FIG. 3 shows an electron photomicrograph of a cross-section of a CIGS film made according to the present invention. The CIGS disc, as described above was ablated as follows. The target disc was placed in deionized water at 3 millimeters below the surface of the water. The pulsed laser was set at a repetition rate of 500 kHz, a pulse energy of 10 μJ, a pulse duration of 700 femtoseconds, and wavelength of 1000 nanometers. The laser beam was focused with a 170 millimeter lens onto the target disc. The beam was rastered at a linear speed of 2 meters per second and greater during the ablation. The total ablation time was approximately 30 minutes. The nanoparticle solution was then dropped onto a substrate of silicon. A drop of the solution was dried at room temperature in ambient air to obtain the thin film. Other application methods such as blade spreading, spin coating, screen printing, and ink jet printing can also be used with the present invention.

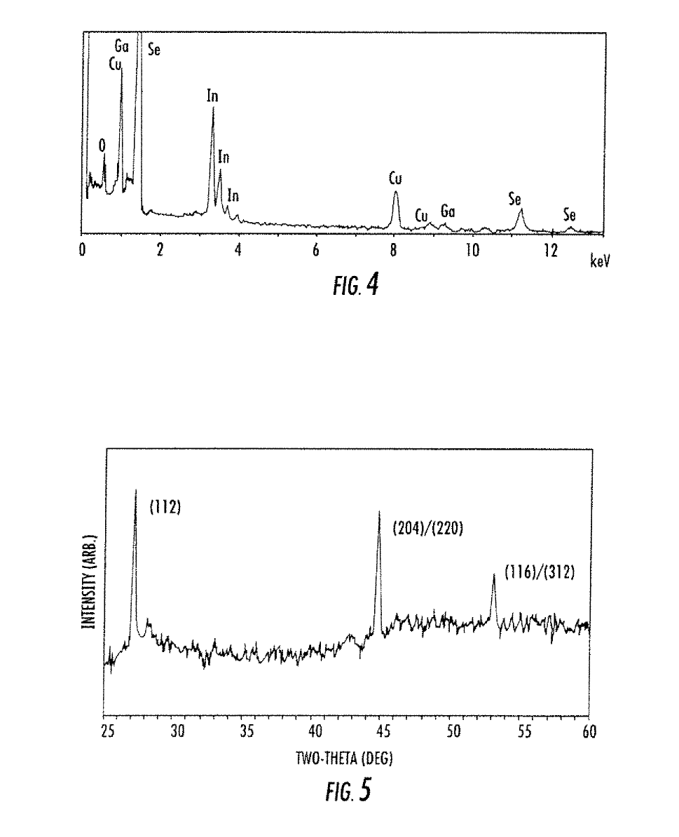

FIG. 4 displays an energy dispersive x-ray spectrum of a CIGS thin film produced according to the present method as described above for FIG. 3. The characteristic x-ray emissions are identified for all the four constitute elements of Cu, In, Ga, and Se. Quantification of the emission intensity gives an atomic ratio for the film of Cu:In:Ga:Se to be 213%:193%:4.7%:54.6%, which is very close to the nominal value of the initial target as described above. This confirms that the present method maintains the composition of the target material in the nanoparticles and in thin films produced from them.

FIG. 5 displays an x-ray diffraction pattern of a CIGS thin film produced according to the present invention method as described above for FIG. 3. The major diffraction peaks of 112, 204, and 116 confirm that the film has the desired chalcopyrite crystal phase of CIGS. Thus, the present invention also produces nanoparticles and thin films from them having the same crystal structure as the target material. The inventors have also found that the desired correct chalcopyrite crystalline phase is obtained after drying the CIGS film at room temperature. This demonstrates another advantage of the current method, which is the ability to use low processing temperatures. Although there is no doubt that further annealing in a selenium atmosphere can further prove the structural quality of the produced films the successful fabrication of polycrystalline CIGS films at room temperature will significantly reduce the energy cost of subsequent annealing steps.

While not wishing to be bound to a particular theory, the inventors theorize that the particular laser-induced phase transitions during pulsed laser ablation according to the present invention lead to the desired maintenance of stoichiometry and crystalline structure. Because of the very short laser pulses both heat and pressure quickly accumulate in the irradiated volume. The transient temperature can reach as high as 5000° C. and the transient pressure can reach the GPa range. The buildup up time of these extreme conditions is typically on the order of 2 to 30 picoseconds, allowing for negligible heat and volume relaxation, especially for dielectrics with low carrier concentration. Under such extreme conditions the material removal occurs in an explosive fashion, the time scale of which is on the order of nanoseconds. This timescale is much shorter than the time required for compositional and crystalline structural changes, which typically takes microseconds and longer to occur. Thus, the ablation is over and the nanoparticles created before changes in composition and crystal structure can occur.

The foregoing invention has been described in accordance with the relevant legal standards, thus the description is exemplary rather than limiting in nature. Variations and modifications to the disclosed embodiment may become apparent to those skilled in the art and do come within the scope of the invention. Accordingly, the scope of legal protection afforded this invention can only be determined by studying the following claims.

We claim:

1. A method of producing nanoparticles of solar light absorbing compound materials from a compound target, comprising the steps of:
a) providing a bulk target of a solar light absorbing compound material in contact with a liquid;
b) irradiating the target with a pulsed laser beam and ablating the target thereby producing nanoparticles of the target; and
c) collecting the nanoparticles, wherein the nanoparticles maintain the stoichiometry and crystalline structure of the target.

2. The method of claim 1, wherein step a) comprises providing a binary compound material composed of elements selected from groups IIB and VIA of the Periodic Table as the target.

3. The method of claim 1, wherein step a) comprises providing a ternary compound material composed of elements selected from groups IB, IIIA and VIA of the Periodic Table as the target.

4. The method of claim 1, wherein step a) comprises providing a quaternary compound material composed of elements selected from groups IB, IIB, IIIA, IVA and VIA of the Periodic Table as the target.

5. The method of claim 1, wherein step a) comprises providing as the target one of CdTe, CdSe, CuInSe₂, CuInS₂, CuInGaSe₂, CuInGaS₂, Cu₂ZnSnS₄ or Cu₂ZnSnSe₄.

6. The method of claim 1, wherein step a) comprises providing as the target a binary, ternary, or quaternary alloy of copper, indium, gallium, zinc, or tin.

7. The method of claim 1, wherein step b) comprises irradiating the target with a pulsed laser beam having a pulse duration in the range from about 10 femtoseconds to 10 nanoseconds.

8. The method of claim 7, wherein step b) comprises irradiating the target with a pulsed laser beam having a pulse duration in the range from about 10 femtoseconds to 200 picoseconds.

9. The method of claim 1, wherein step b) comprises irradiating the target with a pulsed laser beam having a pulse energy in the range from about 100 nano-Joule to 10 milli-Joule.

10. The method of claim 1, wherein step b) comprises irradiating the target with a pulsed laser beam having a pulse energy from about 1 micro-Joule to 10 micro-Joule.

11. The method of claim 1, wherein step b) comprises irradiating the target with a pulsed laser beam having a pulse repetition rate less than about 100 MHz.

12. The method of claim 11, wherein step b) comprises irradiating the target with a pulsed laser beam having a pulse repetition rate in the range from about 100 kHz to 1 MHz.

13. The method of claim 1, wherein step b) comprises irradiating the target with a pulsed laser beam having a wavelength in the UV, visible, or near infrared range.

14. The method of claim 1, wherein step b) comprises moving the laser beam over the target using a vibration mirror.

15. The method of claim 14, wherein the vibration mirror has a frequency of 10 Hz or greater and an angular amplitude of 0.1 mrad or greater such that the laser beam focal spot moves at speed of 0.01 meters per second or greater over the target surface.

16. The method of claim 1, wherein step b) comprises providing a pulsed laser beam having a focal spot diameter in the range from about 20 to 40 microns.

17. The method of claim 1, wherein step b) comprises producing nanoparticles having a size distribution of from about 2 nanometers to 200 nanometers.

18. The method of claim 1, wherein step a) comprises providing the target submerged in a liquid and wherein step b) comprises irradiating the target in the liquid with a pulsed laser beam.

19. The method of claim 1, wherein step a) comprises providing as the liquid deionized water, organic solvents, or liquid nitrogen.

20. The method of claim 1, wherein step a) the liquid further comprises a surfactant.

21. The method of claim 1, wherein step a) further comprises circulating the liquid past the target at a rate of 1.0 milliliters per second or greater.

22. The method of claim 1, further comprising the steps of:
d) applying the collected nanoparticles to a substrate thereby forming a solar light absorbing thin film on the substrate.

23. The method of claim 22, wherein step d) further comprises applying the collected nanoparticles in a solution to a substrate by drop spreading, spin coating, blade spreading, screen printing, or ink jet printing.

24. The method of claim 22, wherein step d) comprises applying the collected nanoparticles to a substrate comprising a semiconductor, a glass, a polymer film, a metal, a metal coated glass, or a metal foil further comprising using as the metal one of molybdenum, copper, titanium, or a mixture thereof.

25. A photovoltaic solar cell device comprising a solar light absorbing layer fabricated by the method of claim 22.
